(19) United States
(12) Patent Application Publication
(10) Pub. No.: US 2026/0323870 A1
(43) Pub. Date: Oct. 15, 2026

(54) UNIFORM-TEMPERATURE RADIATOR WITH MULTI-FLOW CHANNEL

(71) Applicant: YANGZHOU GUOYANG ELECTRONIC CO., LTD., Jiangsu (CN)

(72) Inventors: Ting PAN, Jiangsu (CN); Jianxiang XIAO, Jiangsu (CN); Yang YANG, Jiangsu (CN); Fengbin HAO, Jiangsu (CN); Jie LIU, Jiangsu (CN)

(73) Assignee: YANGZHOU GUOYANG ELECTRONIC CO., LTD., Jiangsu (CN)

(21) Appl. No.: 18/867,446

(22) PCT Filed: Feb. 20, 2024
(86) PCT No.: PCT/CN2024/077709

§ 371 Date: Nov. 20, 2024

(30) Foreign Application Priority Data
Dec. 22, 2023 (CN) 202311780107.8

(51) Int. Cl. H05K 7/20

(52) U.S. Cl. CPC H05K 7/20254; H05K 7/20272; H05K 7/20927

(57) ABSTRACT

The present disclosure discloses a uniform-temperature radiator with a multi-flow channel, and relates to the technical field of the power-electronic power module. The main part of the radiator includes a water inlet and a water outlet arranged at the front and rear ends of the base plate, and a multi-channel located at an intermediate part of the base plate. The water inlet is in communication with a front end of the multi-channel through a divider A, and the water outlet is in communication with a rear end of the multi-channel through a divider B. The divide A is connected to the water inlet and the multi-channel, and is configured to distribute the cooling liquid from the water inlet to the multi-channel reasonably, and the divider B is configured to collect the cooling liquid from the multi-channel to the water outlet reasonably.

### TECHNICAL FIELD

The present disclosure relates to the technical field of the power-electronic power module, and especially relates to a uniform-temperature radiator with a multi-flow channel.

### BACKGROUND

With the vigorous development of the power-electronic technology in China, the power-electronic power module is gradually transitioning towards the miniaturization and the lightweight development. The frequency of electronic device functions is mainly controlled by the operating voltage of the power module, the higher the voltage of the module is, the more heat is generated.

In the existing cooling technology, the air cooling and the liquid cooling are mostly adopted. In addition, since the cooling flow channels of most radiators are in a straight-through type, as the flow path of the fluid from front to back becomes longer, the temperature of the cooling liquid becomes higher, so that the heat dissipation of the overall module is uneven, and the difference between the junction temperature of the chips is large, thereby resulting in that the reliability of the module is reduced.

In order to improve the uneven heat dissipation of the power-electronic power module, balance the temperature distribution between chips, and ensure the high reliability of the power electronic equipment, it is necessary to develop a more effective uniform-temperature radiator.

### SUMMARY

In view of the above mentioned technical problems, a uniform-temperature with a multi-flow channel is provided in the present disclosure to eliminate the disadvantages of the prior art.

In order to solve the above technical problems, a uniform-temperature with a multi-flow channel is provided in the present disclosure.

Technical effect: the present disclosure solves the problem of the uneven heat dissipation of the overall structure caused by the straight-through flow channels. The cooling liquid is flowed in the flow channel more evenly mainly through improving the structure and the layout of the flow channels, which improves the uniformity of the volume of flow in the liquid cooling flow channel and enables the temperature of the cooling liquid in the cooling flow channel to be kept consistent, so that the uniform-temperature heat-dissipation effect of the radiator is improved, and the local overheating of the power module is avoided, thereby improving the operating performance of the power module.

The technical solutions further defined by the present disclosure are as follows. A uniform-temperature radiator with a multi-channel comprises the base plate, a water inlet and a water outlet respectively arranged at both ends of the base plate, and a multi-channel, a divider A, a divider B are arranged between the water inlet and the water outlet.

A cooling liquid is circulated in the multi-channel, a plurality of sub-channels are arranged in the multi-channel in parallel, and the cooling liquid is circulated in the sub-channels uniformly.

The divider A is arranged between the multi-channel and the water inlet, and is configured to connect the multi-channel and the water inlet to distribute the cooling liquid in the multi-channel uniformly.

The divider B is arranged between the multi-channel and the water outlet, and is configured to connect the multi-channel and the water outlet to collect the cooling liquid in the multi-channel reasonably.

Further, the plurality of sub-channels are arranged in parallel along a up-down direction, and the plurality of sub-channels are extended along a front-rear direction.

Provided is the uniform-temperature radiator with multi-flow channel described above. The divider A includes two main flow channels A symmetrically arranged up and down, one sides of the two main flow channels A converge at the water inlet, and a plurality of sub-flow channels A are arranged on another sides of the two main flow channels A in parallel, a number of the sub-flow channels A is matched with a number of the sub-channels, and each of the sub-flow channels A is in communication with a corresponding one of the sub-channels.

Provided is the uniform-temperature radiator with multi-flow channel described above. The diverter B includes two main flow channels B symmetrically arranged up and down, one sides of the two main flow channels B converge at the water inlet, and a plurality of sub-flow channels B are arranged on another sides of the two main flow channels B in parallel, a number of the sub-flow channels B is matched with a number of the sub-channels, and each of the sub-flow channels B is in communication with a corresponding one of the sub-channels.

Provided is the uniform-temperature radiator with multi-flow channel described above. Each of the sub-flow channels A or each of the sub-flow channels B is in a Z-shaped channel structure, and the plurality of sub-flow channels A or the plurality of sub-flow channels B on a same side are arranged in parallel along a up-down direction.

Provided is the uniform-temperature radiator with multi-flow channel described above. Widths of the plurality of sub-flow channels A are decreased from upper and lower sides of the divider A to an intermediate part of the divider A, and widths of the plurality of sub-flow channels B are decreased from upper and lower sides of the divider B to an intermediate part of the divider B.

Provided is the uniform-temperature radiator with multi-flow channel described above. Each of the sub-flow channels A or the sub-flow channels B includes a contraction section, a transition section, and an expansion section arranged in sequence, the contraction section is located approximated to the water inlet, the transition section is located approximate to the water outlet, and the transition section is located at an intermediate of the base plate, cross-sectional dimensions of the contraction section, the transition section and the expansion section are gradually increased.

Provided is the uniform-temperature radiator with multi-flow channel described above. Angles of connections among the contraction section, the transition section and the expansion section are set as an obtuse angle.

The beneficial effects of the present disclosure are as follows.
(1) In the present disclosure, the structure of each of the sub-flow channel is a Z-shaped flow channel, which not only enables the cooling liquid to be flowed more uniformly in the liquid cooling flow channel, improves the uniformity of the volume of flow in the liquid cooling flow channel, but also enables the temperature of the cooling liquid in the flow channels to be kept consistent, and improves the uniform heat dissipation effect of the radiator.
(2) In the present disclosure, the widths of the plurality of sub-flow channels are decreased from the upper and lower sides to the intermediate part, which enables the flow velocities of the flow channels located on upper and lower sides to be slower than that of the flow channel locate at the intermediate part, so that the heat exchange between the upper and lower sides are performed more sufficient, and the heat dissipation effect is better, thereby alleviating the phenomenon of the local overheating of the module.
(3) In the present disclosure, the contraction section, the transition section and the expansion section are arranged on the sub-flow channel along a flow direction of the cooling liquid from front to back, so that the flow velocity of the cooling liquid approximate to the water inlet is faster, and the flow velocity of the cooling liquid approximate to the water outlet is slower, thereby solving the problem of the temperature imbalance of the power module.
(4) In the present disclosure, the proportion of the widths of the sub-flow channels decreasing from the upper and lower sides to the intermediate part ranges from 10% to 20%, but the proportion is not limited to this value, it requires to be set according to the heating performance of the power module.
(5) In the present disclosure, the problem of the uneven overall heat dissipation caused by the straight-through flow channel is solved, the cooling liquid is flowed in flow channel more evenly mainly through improving the structure and the layout of the flow channels, which improves the uniformity of the volume of flow in the liquid cooling flow channel, and enables the temperature of the cooling liquid in the cooling flow channel to be kept consistent, so that the uniform temperature heat dissipation effect of the radiator is improved, and the local overheating of the power module is avoided, thereby improving the operating performance of the power module.

### BRIEF DESCRIPTION OF THE DRAWINGS

FIG. 1 illustrates a schematic structural diagram of a structure of a uniform-temperature radiator with a multi-channel in an embodiment of the present disclosure.

FIG. 2 illustrates a schematic structural diagram of a diverter A and a diverter B in an embodiment of the present disclosure.

FIG. 3 illustrates a partial schematic diagram of a sub-flow channel in an embodiment of the present disclosure.

In which, 1. Base plate; 2. Water inlet; 3. Water outlet; 4. Multi-channel; 5. Sub-channel; 6. Diverter A; 7. Diverter B; 8. Main flow channel A; 81. Sub-flow channel A ; 9. Main flow channel B; 91. Sub-flow channel B.

### DETAILED DESCRIPTION OF THE EMBODIMENTS

In order to make the objectives, the technical solutions and the advantages of the present disclosure clearer, the detailed descriptions will be given below with reference to the accompanying drawings and the specific implementations. In the following descriptions, numerous specific details are set forth in order to provide a thorough understanding of the present disclosure. However, the present disclosure can be implemented in many other ways different from those described herein. Those skilled in the art can make similar improvements without violating the connotation of the present disclosure. Therefore, the present disclosure is not limited to the specific embodiments disclosed below.

It should be noted that when a component is referred to as being “fixedly arranged on” another component, the component can be directly on another element or an intervening component is provided. When a component is referred to be “connected to” the another component, the component can be directly connected to another component or an intervening component can be provided. The terms “vertical”, “horizontal”, “left”, “right” and similar expressions used herein are merely for the illustrative purposes and do not represent the unique implementation.

Unless otherwise defined, all technical and scientific terms used herein have the same meaning as commonly understood by one of ordinary skill in the art to which the present disclosure belongs. The terms used herein in the description of the present disclosure is merely for the purpose of describing the specific embodiments, and are not intended to limit the present disclosure.

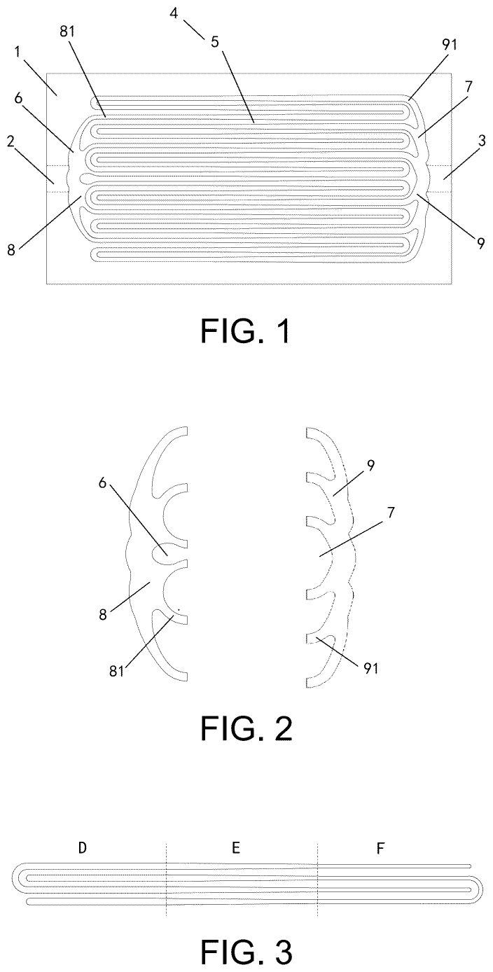

A uniform-temperature radiator with a multi-channel is provided in this embodiment, and the structure of the radiator is illustrated in FIG. 1. The main part of the radiator includes a water inlet 2 and a water outlet 3 arranged at the front and rear ends of the base plate 1 (the base plate 1 is a metal plate), and a multi-channel 4 located at intermediate part of the base plate 1. The water inlet 2 and the water outlet 3 are located at an intermediate position of the base plate 1, and the water inlet 2 and the water outlet 3 are located on the same horizontal line and are distributed in an I shape.

The water inlet 2 is in communication with a front end of the multi-channel 4 through the diverter A 6, the water outlet 3 is in communication with a rear end of the multi-channel 4 through the diverter B 7. The diverter A 6 is connected to the water outlet 2 and the multi-channel 4, and is configured to reasonably distribute the cooling liquid from the water inlet 2 to the multi-channel 4, and the diverter B 7 is configured to reasonably collect the cooling liquid from the multi-channel 4 to the water outlet 3.

The multi-channel 4 includes a plurality of sub-channels 5 arranged in parallel along a up-down direction, and the sub-channels 5 is extended along a z-shaped path in the up-down direction. A plurality of sub-channels 5 are arranged in parallel, so that the cooling liquid in the liquid cooling flow channel is flowed more uniformly, and the temperature of the cooling liquid in each of the sub-channels 5 is kept consistent, thereby ensuring that the cooling liquid in the liquid cooling flow channel can be heat-exchanged with the power module uniformly, and avoiding that the local overheating is generated on the power module to affect the operating performance. It is worth noting that in this embodiment, sub-channels arranged in parallel along the up-down direction are provided, which is not limited to this number in the actual application, and should be set according to the requirement.

Each of the sub-channels 5 is constructed as a Z-shaped flow channel to increase the contact area between the sub-channel 5 and the power module, thereby ensuring that the contact area between the liquid cooling flow channel and the power module is enough large to allow the cooling liquid to fully cool the power module during the flow, thus improving the heat dissipation performance of the radiator.

In the uniform-temperature radiator with the multi-channel 4 provided in embodiment of the present disclosure, a plurality of the sub-channel 5 are arranged in parallel, and each of the sub-channels 5 is in a Z-shaped channel, which not only enables the cooling liquid to flow more uniform in the liquid cooling channel, that is, the uniformity of the flow in the liquid cooling channel is improved, but also enables the temperature of the cooling liquid in the cooling channel to be kept consistent, thereby improving the cooling effect of the uniform-temperature radiator on the power module, and avoiding the local overheating of the power module, thus improving the operating performance of the power module.

As illustrated in FIG. 2, the diverter A 6 includes two main flow channels A 8 located at upper and lower sides of the diverter A 6. The two main flow channels A 8 converge at the water inlet 2 and are in communication with the water inlet 2. A plurality of sub-flow channels A 81 are arranged on each of the main flow channels A 8, and the widths of the plurality of sub-flow channels A 81 of the diverter A 6 are decreased from the upper and lower sides to the intermediate part. The intermediate part of the diverter A 6 is in a drop-shape between the two middlemost sub-channels A 81, and the tip of the drop shaped part faces the water inlet 2.

As illustrated in FIG. 2, the diverter B 7 includes two main flow channels B 9 located at upper and lower sides of the diverter B 7. The two main flow channels B 9 converge at the water inlet 2 and are in communication with the water inlet 2. A plurality of sub-flow channels B 91 are arranged on each of the main flow channels B 9, the widths of the plurality of sub-flow channels B 91 of the diverter B 7 are decreased from the upper and lower sides to the intermediate part.

The widths of the sub-channels 5 are decreased from the upper and lower sides to the intermediate part, which can implements the reasonable distribution of the cooling liquid. Through reasonably setting the decreasing proportion of the width of the sub-channels 5, the flow of the cooling liquid in the sub-channels 5 is in a reasonable state, and the radiator has a more balanced heat dissipation performance. In this embodiment, the proportion of the width of the sub-channel 5 decreasing from the upper and lower sides to the intermediate part ranges from 10% to 20%, but the proportion is not limited to this value, and the proportion requires to be set according to the heating performance of the power module.

It is easy to see that the volume of the fluid flowing into a channel should be equal to the volume of the fluid flowing out of a channel at an arbitrary time instant without considering the compressibility of the fluid. The narrow channel and the small flow area necessarily mean that the requirement for conservation of the fluid flow in and out must be satisfied by increasing the flow velocity.

As illustrated in FIG. 3, the cross-section of each of the sub-channels 5 is set to be smaller approximate to the cooling liquid inlet 2 to increase the flow velocity of the cooling liquid and reduce the heat transfer area between the cooling liquid and the radiator. The cross-section of each of the sub-channels 5 is set to be larger approximate to the cooling liquid inlet 3 to reduce the flow velocity of the cooling liquid and increase the heat transfer area between the cooling liquid and the radiator. In this way, the cooling liquid absorbs the heat in the contraction section D approximate to the water inlet 2 and enters the transition section E and the expansion section F, then the flow velocity of the cooling liquid in the transition section E and the expansion section F is slowed down and the heat exchange area is increased, which enables the heat exchange to be more completely.

In such a way, the temperature difference of the overall module becomes smaller in different areas, which solves the problem in the prior art where the cooling channel is a straight through type, and the flow velocity and heat exchange efficiency of the cooling liquid continuously decrease with the change of the walking path, resulting in inconsistent heat dissipation effects of the cooling liquid on different positions of the power module, and causing excessive temperature difference at the junction of the power module chip.

In this embodiment, the contraction section D is smoothly connected to the expansion section F through the transition section E. The contraction section D and the expansion section F are in a rectangular shape, and the transition section E is in a trapezoidal shape. In comparison with the direct communication between the contraction section D and the transition section E where the connection is as a right angle, the design of adding the transition section E can reduce the flow resistance of the cooling liquid.

In this embodiment, the angles of the connections among the contraction section, the transition section and the expansion section are set at an obtuse angle, which reduces the impact on the cooling liquid flow caused by the size variation of the cooling flow channel.

It is worth noting that, in this embodiment, the proportion of the length of the three flow channels of the contraction section D, the transition section E and the expansion section F is 1:1:1. This proportion is merely for illustration, and the proportion is not limited to this proportion, which is required to be set according to the heating performance of the power module.

In comparison with the existing straight-through radiator, the uniform-temperature radiator with the multi-channel 4 designed in the embodiments of the present disclosure is modeled and simulated, according to the simulation result, the maximum junction temperature of the chip is reduced to a certain extent and the junction temperature difference between the chips is reduced by approximately 15%, thus proving that the radiator has a better uniform-temperature heat dissipation performance.

In addition to the above embodiments, the present disclosure may also have other embodiments. An arbitrary technical solution formed by the equivalent substitution or the equivalent transformation falls within the protection scope of the present disclosure.

What is claimed is:

1. A uniform-temperature radiator with a multi-flow channel, comprising a base plate, a water inlet and a water outlet respectively arranged at both ends of the base plate, wherein
a multi-channel, a divider A, a divider B are arranged between the water inlet and the water outlet;
a cooling liquid is circulated in the multi-flow channel, a plurality of sub-channels are arranged in the multi-channel in parallel, and the cooling liquid is circulated in the sub-channels uniformly;
the divider A is arranged between the multi-channel and the water inlet, and is configured to connect the multi-channel and the water inlet to distribute the cooling liquid in the multi-channel uniformly; and
the divider B is arranged between the multi-channel and the water outlet, and is configured to connect the multi-channel and the water outlet to collect the cooling liquid in the multi-channel reasonably.

2. The uniform-temperature radiator with the multi-flow channel according to claim 1, wherein the plurality of sub-channels are arranged in parallel along an up-down direction, and the plurality of sub-channels are extended along a front-rear direction.

3. The uniform-temperature radiator with multi-flow channel according to claim 1, wherein the divider A includes two main flow channels A symmetrically arranged up and down, one sides of the two main flow channels A converge at the water inlet, and a plurality of sub-flow channels A are arranged on another sides of the two main flow channels A in parallel, a number of the sub-flow channels A is matched with a number of the sub-channels, and each of the sub-flow channels A is in communication with a corresponding one of the sub-channels.

4. The uniform-temperature radiator with the multi-flow channel according to claim 3, wherein the diverter B includes two main flow channels B symmetrically arranged up and down, one sides of the two main flow channels B converge at the water inlet, and a plurality of sub-flow channels B are arranged on another sides of the two main flow channels B in parallel, a number of the sub-flow channels B is matched with a number of the sub-channels, and each of the sub-flow channels B is in communication with a corresponding one of the sub-channels.

5. The uniform-temperature radiator with the multi-flow channel according to claim 4, wherein each of the sub-flow channels A or each of the sub-flow channels B is in a Z-shaped channel structure, and the plurality of sub-flow channels A or the plurality of sub-flow channels B on a same side are arranged in parallel along a up-down direction.

6. The uniform-temperature radiator with the multi-flow channel according to claim 3, wherein widths of the plurality of sub-flow channels A are decreased from upper and lower sides of the divider A to an intermediate part of the divider A, and widths of the plurality of sub-flow channels B are decreased from upper and lower sides of the divider B to an intermediate part of the divider B.

7. The uniform-temperature radiator with the multi-flow channel according to claim 1, wherein each of the sub-flow channels A or the sub-flow channels B includes a contraction section, a transition section, and an expansion section arranged in sequence, the contraction section is located approximated to the water inlet, the transition section is located approximate to the water outlet, and the transition section is located at an intermediate of the base plate, cross-sectional dimensions of the contraction section, the transition section and the expansion section are gradually increased.

8. The uniform-temperature radiator with the multi-flow channel according to claim 1, wherein angles of connections among the contraction section, the transition section and the expansion section are set as an obtuse angle.
